(19) United States
(12) Patent Application Publication
(10) Pub. No.: US 2025/0079225 A1
(43) Pub. Date: Mar. 6, 2025

(54) DICING TAPE AND METHOD OF MANUFACTURING SEMICONDUCTOR PACKAGE USING THE SAME

(71) Applicant: Samsung Electronics Co., Ltd., Suwon-si (KR)

(72) Inventor: Hajung LEE, Suwon-si (KR)

(73) Assignee: Samsung Electronics Co., Ltd., Suwon-si (KR)

(21) Appl. No.: 18/815,933

(22) Filed: Aug. 27, 2024

(30) Foreign Application Priority Data
Sep. 6, 2023 (KR) 10-2023-0118556

(51) Int. Cl. H01L 21/683; H01L 21/48; H01L 23/00

(52) U.S. Cl. CPC H01L 21/6836; H01L 24/97; H01L 21/4853; H01L 2224/95001

(57) ABSTRACT

A dicing tape may include a base layer, an intermediate layer on the base layer, and an adhesive layer on the intermediate layer. The adhesive layer may include a first adhesive film and a second adhesive film. The first adhesive film may be formed in a circular shape in a central portion of the adhesive layer and may have a first adhesive force. The second adhesive film may surround the first adhesive film to provide an interface between the first adhesive film and the second adhesive film. The second adhesive film may have a second adhesive force and the second adhesive force may be greater than the first adhesive force.

### CROSS-REFERENCE TO RELATED APPLICATION

This application is based on and claims priority under 35 U.S.C. § 119 to Korean Patent Application No. 10-2023-0118556, filed on Sep. 6, 2023 in the Korean Intellectual Property Office, the disclosure of which is incorporated by reference herein in its entirety.

### BACKGROUND

Inventive concepts relate to a dicing tape and a method of manufacturing a semiconductor package using the same, and more particularly, to a highly heat-resistant dicing tape and a method of manufacturing a semiconductor package using the same.

Recently, in the electronic product market, the demand for portable devices is rapidly increasing, and thus miniaturization and weight reduction of electronic components mounted on these electronic products are continuously demanded. For miniaturization and weight reduction of electronic components, semiconductor packages mounted thereon may be demanded to process high-capacity data while volumes of the semiconductor packages may be gradually reduced. High integration and single packaging of semiconductor chips mounted on such semiconductor packages may be demanded. To satisfy such demands, a substrate structure may be diced to form a plurality of semiconductor dies, and each of the plurality of semiconductor dies may be manufactured into a semiconductor package. Therefore, a dicing tape with excellent semiconductor die pick-up property may be demanded after the dicing process of the substrate structure.

### SUMMARY

Inventive concepts provide a dicing tape that may provide strong adhesion to a ring frame and improved pick-up properties of semiconductor dies, by using an adhesive layer including adhesive films with different adhesive forces.

Inventive concepts provide a method of manufacturing a semiconductor package using a dicing tape that may provide strong adhesion to a ring frame and improved pick-up properties of semiconductor dies to facilitate separation of the semiconductor dies from the dicing tape, by using an adhesive layer including adhesive films with different adhesive forces.

In addition, aspects of inventive concepts are not limited to the aspects mentioned above, and other aspects may be clearly understood by one of ordinary skill in the art from the following descriptions.

According to an embodiment of inventive concepts, a dicing tape may include a base layer, an intermediate layer on the base layer, and an adhesive layer on the intermediate layer, wherein the adhesive layer may include a first adhesive film and a second adhesive film. The first adhesive film may have a circular shape in a central portion of the adhesive layer and may have a first adhesive force. The second adhesive film may surround the first adhesive film and may provide an interface between the first adhesive film and the second adhesive film. The second adhesive film may have a second adhesive force. The second adhesive force may be greater than the first adhesive force.

According to an embodiment of inventive concepts, a dicing tape may include a base layer; an intermediate layer on the base layer; and an adhesive layer on the intermediate layer, wherein the adhesive layer may include a first adhesive film, a second adhesive film, and a third adhesive film. The first adhesive film may have a circular shape in a central portion of the adhesive layer and may have a first adhesive force. The second adhesive film may have a ring-like shape and may surround the first adhesive film to provide a first interface between the first adhesive film and the second adhesive film. The second adhesive film may have a second adhesive force. The second adhesive force may be greater than the first adhesive force. The third adhesive film may surround the second adhesive film to provide a second interface between the second adhesive film and the third adhesive film. The third adhesive film may have the first adhesive force.

According to an embodiment of inventive concepts, a method of manufacturing a semiconductor package may include preparing a substrate structure with a first surface attached to a carrier substrate; attaching a ring frame to edges of a dicing tape; attaching a second surface of the substrate structure to a center of the dicing tape, the second surface of the substrate structure being opposite the first surface of the substrate structure; performing an ultraviolet (UV) treatment process on the carrier substrate; irradiating a laser beam to the carrier substrate to separate the carrier substrate from the substrate structure; attaching solder balls to the first surface of the substrate structure and performing a heat treatment process thereon; separating the substrate structure into a plurality of semiconductor dies by cutting the substrate structure along a dicing line; debonding and picking up the plurality of semiconductor dies from the dicing tape; and forming each of the plurality of semiconductor dies into a semiconductor package. The dicing tape may include a base layer, an intermediate layer on the base layer, and an adhesive layer on the intermediate layer. The adhesive layer may include a first adhesive film and a second adhesive film. The first adhesive film may have a circular shape in a central portion of the adhesive layer and may have a first adhesive force. The second adhesive film may surround the first adhesive film to provide an interface between the first adhesive film and the second adhesive film. The second adhesive film may have a second adhesive force. The second adhesive force may be greater than the first adhesive force.

### BRIEF DESCRIPTION OF THE DRAWINGS

Embodiments of inventive concepts will be more clearly understood from the following detailed description taken in conjunction with the accompanying drawings in which:

FIGS. 1A and 1B are schematic diagrams showing a dicing tape according to an embodiment;

FIG. 2 is a flowchart of a method of manufacturing a dicing tape, according to an embodiment;

FIG. 3 is a cross-sectional view of a method of manufacturing a dicing tape, according to an embodiment;

FIGS. 4A and 4B are schematic diagrams showing a dicing tape according to another embodiment;

FIGS. 5A and 5B are schematic diagrams showing a dicing tape according to another embodiment;

FIG. 6 is a flowchart of a method of manufacturing a semiconductor package, according to an embodiment;

FIGS. 7 to 16 are cross-sectional views showing, in a process sequence, a method of manufacturing a semiconductor package, according to an embodiment; and

FIGS. 17 to 19 are views showing other semiconductor packages manufactured by the method of manufacturing a semiconductor package, according to an embodiment.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%. While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., +10%).

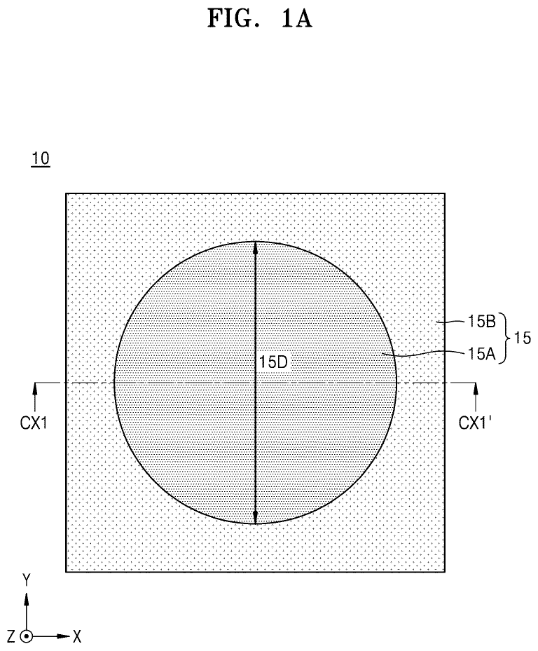

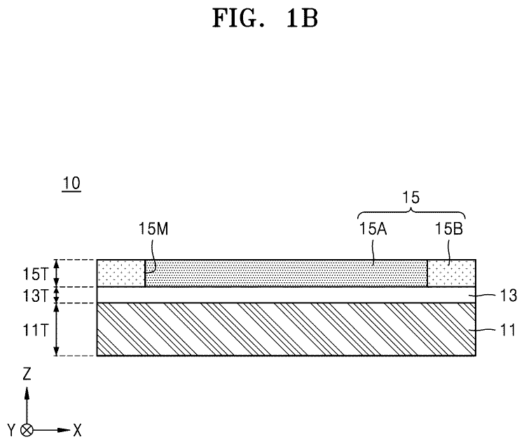

FIGS. 1A and 1B are schematic diagrams showing a dicing tape according to an embodiment.

In detail, FIG. 1A is a plan view of a dicing tape 10 according to an embodiment, and FIG. 1B is a cross-sectional view of the dicing tape 10 of FIG. 1A taken along a line CX1-CX1′.

Referring to FIGS. 1A and 1B together, the dicing tape 10 includes a base layer 11, an intermediate layer 13 on the base layer 11, and an adhesive layer 15 on the intermediate layer 13.

The base layer 11 may be referred to as a base film. The base layer 11 may include a synthetic resin having a certain elastic modulus. The certain elastic modulus may be a certain Young's modulus. The base layer 11 may include, for example, any one selected from among polyethylene terephthalate (PET), polyethylene naphthalate (PEN), polyether ether ketone (PEEK), and polyimide (PI). The base layer 11 may have a first thickness 11T. According to some embodiments, the first thickness 11T of the base layer 11 may be from about 30 micrometers to about 40 micrometers. The base layer 11 may increase the physical reliability of the dicing tape 10 by physically supporting the adhesive layer 15 during the processing of a substrate structure. Also, the base layer 11 may increase the chemical reliability of the dicing tape 10 by preventing moisture absorption (moisture penetration or moisture inhalation) that may occur during the processing of the substrate structure.

The intermediate layer 13 may be located on the base layer 11. The intermediate layer 13 may be referred to as an anchor film. When a substrate structure to which a carrier substrate is attached is mounted on the dicing tape 10, the intermediate layer 13 may physically perform a buffering role. The intermediate layer 13 may have a second thickness 13T. According to some embodiments, the second thickness 13T of the intermediate layer 13 may be from about 1 micrometer to about 10 micrometers. Here, the second thickness 13T of the intermediate layer 13 may be less than the first thickness 11T of the base layer 11. The intermediate layer 13 may include, for example, ultraviolet (UV) curable synthetic resin or non-UV curable synthetic resin. According to some embodiments, the intermediate layer 13 may include an acrylate polymer and a cross-linking agent.

As a monomer composition constituting the acrylate polymer, a monomer such as 2-ethylhexyl acrylate, 2-hydroxyethyl acrylate, and butyl acrylate may be included in a range from about 50 weight % to about 90 weight %. Also, the acrylate polymer may include a monomer such as methacrylate, vinyl acetate, and styrene as a cohesive component in a range from about 10 weight % to about 40 weight %. Also, the acrylate polymer may include a monomer such as acrylic acid and methyl methacrylic acid as a functional component in a range from about 2 weight % to about 20 weight %. However, monomer compositions constituting the acrylate polymer are not limited thereto. In the acrylate polymer, the total amount of the monomer composition may be 100 weight % or less.

The cross-linking agent may be used without particular limitation as long as the cross-linking agent contains isocyanate. For example, the cross-linking agent may include at least one selected from a group consisting of alicyclic compounds such as isophorone diisocyanate, methylenebiscyclohexane diisocyanate, etc.; aliphatic compounds such as hexamethylene diisocyanate; and aromatic compounds such as toluene diisocyanate, methylenediphenyl diisocyanate, m-tetramethylxylylene diisocyanate, etc., but inventive concepts are not limited thereto.

The adhesive layer 15 may be located on the intermediate layer 13. The adhesive layer 15 may be referred to as an adhesive film. Also, the adhesive layer 15 may include different films including a first adhesive film 15A and a second adhesive film 15B. Here, the first adhesive film 15A is formed in a circular shape in the central portion of the adhesive layer 15 and may have a first adhesive force. Also, the second adhesive film 15B surrounds the first adhesive film 15A and may have a second adhesive force that is greater than the first adhesive force.

According to some embodiments, the first adhesive film 15A may have a first diameter 15D. The first diameter 15D of the first adhesive film 15A may be greater than the diameter of a substrate structure, as described below, and may be less than the inner diameter of a ring frame, as described below. The diameter of the substrate structure may correspond to the diameter of a wafer on which a semiconductor process is performed and may be, for example, about 300 millimeters (12 inches). However, inventive concepts are not limited thereto.

According to some embodiments, the level of the top surface of the first adhesive film 15A and the level of the second adhesive film 15B may be substantially identical to each other. In other words, the thickness of the first adhesive film 15A and the thickness of the second adhesive film 15B may be substantially identical to each other. The first adhesive film 15A and the second adhesive film 15B are different films arranged side-by-side on the top surface of the intermediate layer 13, and thus an interface 15M may be formed between the first adhesive film 15A and the second adhesive film 15B. The interface 15M may be arranged in a vertical direction (Z direction) with respect to the top surface of the intermediate layer 13.

When a substrate structure to which a carrier substrate is attached is mounted on the dicing tape 10, the adhesive layer 15 may serve as an adhesive. The adhesive layer 15 may have a third thickness 15T. According to some embodiments, the third thickness 15T of the adhesive layer 15 may be from about 20 micrometers to about 30 micrometers. Here, the third thickness 15T of the adhesive layer 15 may be less than the first thickness 11T of the base layer 11 and greater than the second thickness 13T of the intermediate layer 13.

The adhesive layer 15 may include, for example, a highly heat-resistant pressure sensitive adhesive (PSA). According to some embodiments, the adhesive layer 15 may include an acrylate polymer, a cross-linking agent, and a photo initiator. The acrylate polymer and cross-linking agent constituting the adhesive layer 15 may be substantially identical to those described above.

The photo initiator may be, for example, at least one selected from a group consisting of benzoin compounds, acetophenone compounds, acylphosphine oxide compounds, titanocene compounds, thioxanthone compounds, amines, and quinones. According to some embodiments, the photo initiator may be 1-hydroxycyclohexyl phenyl ketone, benzoin, benzoin methyl ether, benzoin ethyl ether, benzoin isopropyl ether, benzyl diphenyl sulfide, tetramethylthiuram monosulfide, azobisisobutyronitrile, dibenzyl, diacetyl, and beta-chloroanthraquinone but is not limited thereto.

According to some embodiments, an ultraviolet treatment process may advance curing of the acrylate polymer in the adhesive layer 15 due to a photo initiator. In other words, the polymerization reaction of the acrylate polymer may include a radical polymerization reaction using the photo initiator. However, according to other embodiments, the temperature of the substrate structure may rise to about 150° C. due to a high amount of UV irradiation from a light-emitting diode (LED) used in the semiconductor package manufacturing process, and thus the adhesive force of the adhesive layer 15 may decrease despite the curing.

According to an embodiment, the first adhesive film 15A constituting the adhesive layer 15 may include a highly heat-resistant pressure-sensitive adhesive with a relatively high degree of curing as compared to the second adhesive film 15B, and the second adhesive film 15B constituting the adhesive layer 15 may include a pressure-sensitive adhesive with a relatively low degree of curing as compared to the first adhesive film 15A. In other words, the mixing ratio of the acrylate polymer, the cross-linking agent, and the photo initiator in the first adhesive film 15A may be different from that in the second adhesive film 15B.

Ultimately, since the dicing tape 10 according to inventive concepts uses the adhesive layer 15 including the first adhesive film 15A and the second adhesive film 15B having different adhesive forces, while a ring frame is strongly adhered to the second adhesive film 15B of the dicing tape 10, a semiconductor die may be easily separated from the first adhesive film 15A of the dicing tape 10, and thus the pick-up performance of a semiconductor die from the dicing tape 10 may be improved.

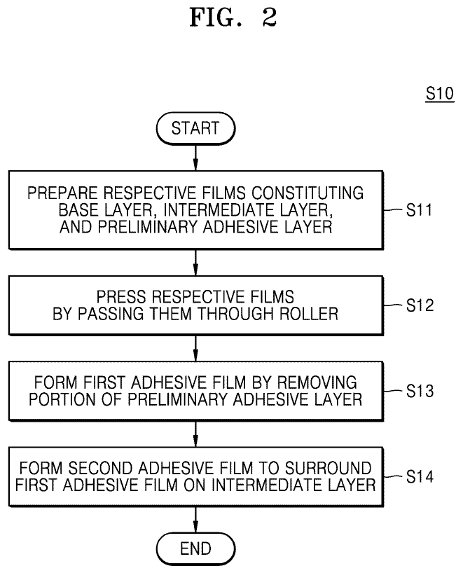

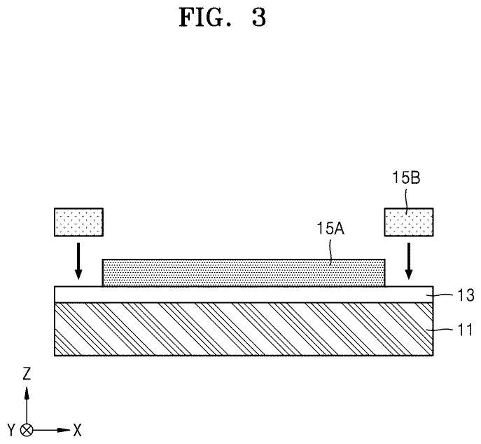

FIG. 2 is a flowchart of a method of manufacturing a dicing tape, according to an embodiment, and FIG. 3 is a cross-sectional view showing a method of manufacturing a dicing tape according to an embodiment.

Referring to FIGS. 2 and 3 together, the method S10 of manufacturing a dicing tape may include a process sequence of first to fourth operations S11 to S14.

In a certain embodiment that may be implemented otherwise, particular operations may be performed in an order different from that described below. For example, two successively described operations may be performed substantially and simultaneously or may be performed in an order opposite to the order described below.

The method S10 of manufacturing a dicing tape according to inventive concepts may include a first operation S11 of preparing respective films constituting the base layer 11, the intermediate layer 13, and a preliminary adhesive layer, a second operation S12 of pressing the respective films by passing them through a roller, a third operation S13 of forming the first adhesive film 15A by removing a portion of the preliminary adhesive layer, and a fourth operation S14 of forming the second adhesive film 15B to surround the first adhesive film 15A on the intermediate layer 13.

Here, the first adhesive film 15A and the second adhesive film 15B may constitute an adhesive layer. When needed, an operation of passing the base layer 11, the intermediate layer 13, the first adhesive film 15A, and the second adhesive film 15B through the roller and pressing them again may be performed.

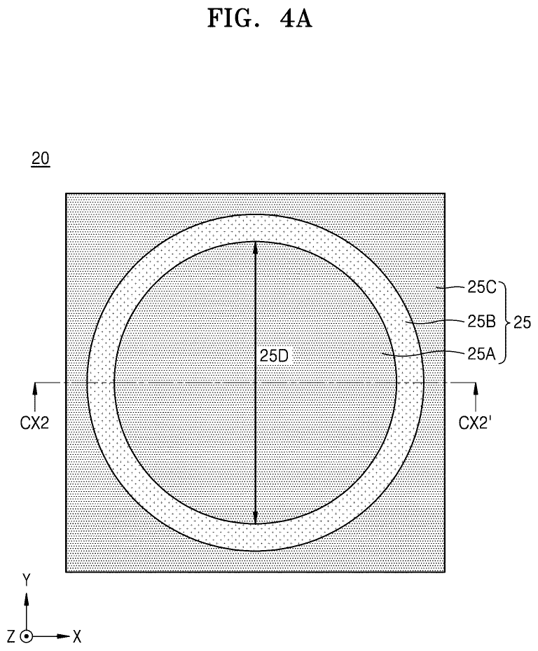

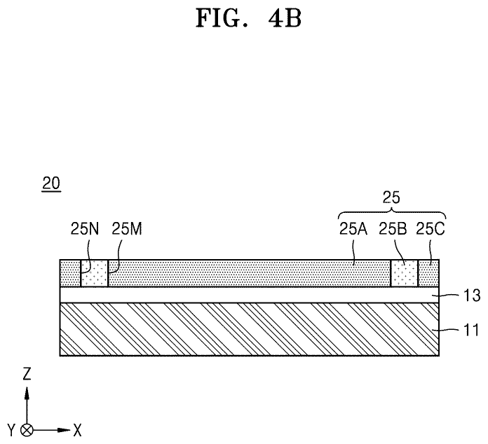

FIGS. 4A and 4B are schematic diagrams showing a dicing tape according to another embodiment.

In detail, FIG. 4A is a plan view of a dicing tape 20 according to an embodiment, and FIG. 4B is a cross-sectional view of the dicing tape 20 of FIG. 4A taken along a line CX2-CX2′.

Most of components constituting the dicing tape 20 described below and materials constituting the components are substantially the same as or similar to those described with reference to FIGS. 1A and 1B above. Therefore, for convenience of explanation, descriptions below will focus on the differences from the dicing tape 10 described above.

Referring to FIGS. 4A and 4B together, the dicing tape 20 includes the base layer 11, the intermediate layer 13 on the base layer 11, and an adhesive layer 25 on the intermediate layer 13.

In the dicing tape 20 according to the present embodiment, the adhesive layer 25 may include different films including a first adhesive film 25A, a second adhesive film 25B, and a third adhesive film 25C. Here, the first adhesive film 25A may be formed in a circular shape in the central portion of the adhesive layer 25 and may have a first adhesive force. Also, the second adhesive film 25B may be formed in a ring-like shape surrounding the first adhesive film 25A, may have a first interface 25M with respect to the first adhesive film 25A, and may have a second adhesive force that is greater than the first adhesive force. Also, the third adhesive film 25C may surround the second adhesive film 25B, may have a second interface 25N with respect to the second adhesive film 25B, and may have the first adhesive force. In other words, the first adhesive film 25A and the third adhesive film 25C may have substantially the same adhesive force.

According to some embodiments, the first adhesive film 25A may have a first diameter 25D. The first diameter 25D may be greater than the diameter of a substrate structure, as described below, and may be less than the inner diameter of a ring frame, as described below. The diameter of the substrate structure may correspond to the diameter of a wafer on which a semiconductor process is performed and may be, for example, about 300 millimeters (12 inches). However, inventive concepts are not limited thereto.

According to some embodiments, the level of the top surface of the first adhesive film 25A, the level of the top surface of the second adhesive film 25B, and the level of the top surface of the third adhesive film 25C may be substantially identical to one another. In other words, the thickness of the first adhesive film 25A, the thickness of the second adhesive film 25B, and the thickness of the third adhesive film 25C may be substantially identical to one another. The first adhesive film 25A and the second adhesive film 25B are different films arranged side-by-side on the top surface of the intermediate layer 13, and thus the first interface 25M may be formed between the first adhesive film 25A and the second adhesive film 25B. Also, the second adhesive film 25B and the third adhesive film 25C are different films arranged side-by-side on the top surface of the intermediate layer 13, and thus the second interface 25N may be formed between the second adhesive film 25B and the third adhesive film 25C. The first interface 25M and the second interface 25N may each be disposed in a direction perpendicular to the top surface of the intermediate layer 13 (Z direction).

According to some embodiments, the first adhesive film 25A and the third adhesive film 25C constituting the adhesive layer 25 may include a highly heat-resistant pressure-sensitive adhesive with a relatively high degree of curing as compared to the second adhesive film 25B, and the second adhesive film 25B constituting the adhesive layer 25 may include a pressure-sensitive adhesive having a relatively low degree of curing as compared to the first adhesive film 25A and the third adhesive film 25C. Also, the first adhesive film 25A constituting the adhesive layer 25 may include a highly heat-resistant pressure-sensitive adhesive having substantially the same degree of curing as the third adhesive film 25C.

In other words, the mixing ratio of the acrylate polymer, the cross-linking agent, and the photo initiator in the first adhesive film 25A may be different from that in the second adhesive film 25B. Also, the mixing ratio of the acrylate polymer, the cross-linking agent, and the photo initiator in the second adhesive film 25B may be different from that in the third adhesive film 25C. However, the mixing ratio of the acrylate polymer, the cross-linking agent, and the photo initiator in the first adhesive film 25A may be identical to that in the third adhesive film 25C.

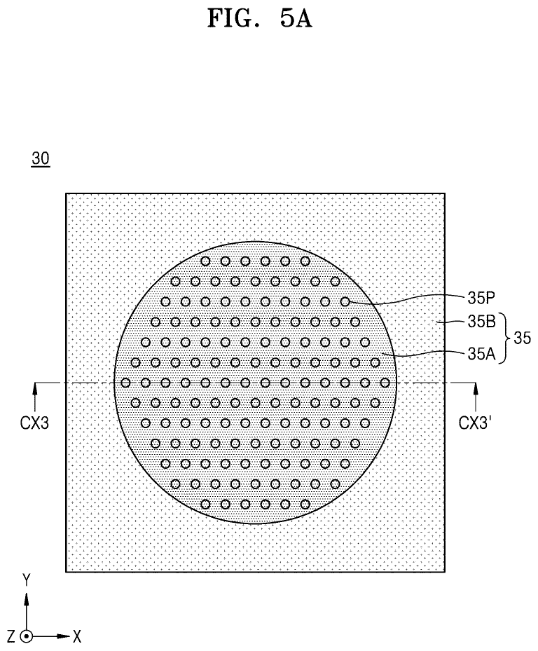

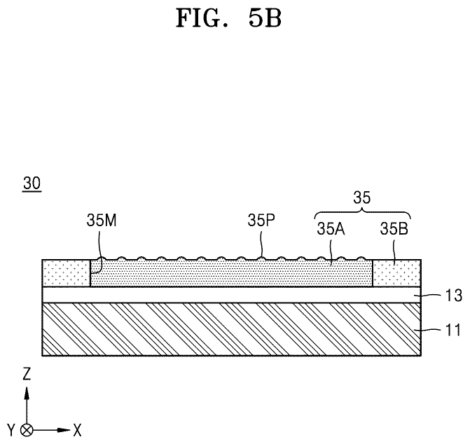

FIGS. 5A and 5B are schematic diagrams showing a dicing tape according to another embodiment.

In detail, FIG. 5A is a plan view of a dicing tape 30 according to an embodiment, and FIG. 5B is a cross-sectional view of the dicing tape 30 of FIG. 5A taken along a line CX3-CX3′.

Most of the components constituting the dicing tape 30 described below and materials constituting the components are substantially the same as or similar to those described with reference to FIGS. 1A and 1B above. Therefore, for convenience of explanation, descriptions below will focus on the differences from the dicing tape 10 described above.

Referring to FIGS. 5A and 5B together, the dicing tape 30 includes a base layer 11, an intermediate layer 13 on the base layer 11, and an adhesive layer 35 on the intermediate layer 13.

In the dicing tape 30 of this embodiment, the top surface of a first adhesive film 35A may be an embossed surface 35P. In other words, the top surface of the first adhesive film 35A may have a concavo-convex structure. Therefore, the contact area with the substrate structure adhered to the top surface of the first adhesive film 35A may be reduced. In contrast, the top surface of a second adhesive film 35B may be flat.

Therefore, in the dicing tape 30 according to the present embodiment, due to the embossed surface 35P, the level of the topmost surface of the first adhesive film 35A in the adhesive layer 35 may be higher than the level of the topmost surface of the second adhesive film 35B. In other words, due to the embossed surface 35P, the thickness of the first adhesive film 35A in the adhesive layer 35 may be greater than the thickness of the second adhesive film 35B.

According to some embodiments, the adhesive layer 35 may include different films including the first adhesive film 35A and the second adhesive film 35B. Here, the first adhesive film 35A may be formed in a circular shape in the central portion of the adhesive layer 35 and may have a first adhesive force. Also, the second adhesive film 35B surrounds the first adhesive film 35A and may have a second adhesive force that is greater than the first adhesive force.

According to some embodiments, the first adhesive film 35A and the second adhesive film 35B are different films arranged side-by-side on the top surface of the intermediate layer 13, and thus an interface 35M may be formed between the first adhesive film 35A and the second adhesive film 35B. The interface 35M may be arranged in a vertical direction (Z direction) with respect to the top surface of the intermediate layer 13.

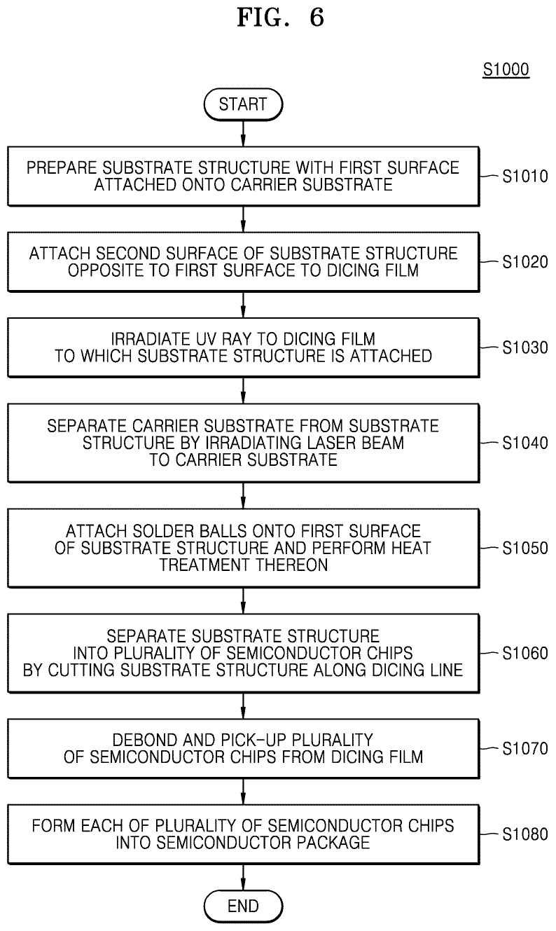

FIG. 6 is a flowchart of a method of manufacturing a semiconductor package, according to an embodiment.

Referring to FIG. 6, the method S1000 of manufacturing a semiconductor package may include first to eighth operations S1010 to S1080.

In a certain embodiment that may be implemented otherwise, particular operations may be performed in an order different from that described below. For example, two successively described operations may be performed substantially and simultaneously or may be performed in an order opposite to the order described below.

The method S1000 of manufacturing a semiconductor package according to inventive concepts may include a first operation S1010 of preparing a substrate structure of which a first surface is attached onto a carrier substrate, a second operation S1020 of attaching a second surface of the substrate structure opposite to the first surface onto a dicing tape fixed to a lower portion of a ring frame, a third operation S1030 of irradiating an UV ray to the dicing tape to which the substrate structure is attached, a fourth operation S1040 of separating the carrier substrate from the substrate structure by irradiating a laser beam to the carrier substrate, a fifth operation S1050 of attaching solder balls onto the first surface of the substrate structure and performing heat treatment thereon, a sixth operation S1060 of separating the substrate structure into a plurality of semiconductor dies by dicing the substrate structure along dicing lines, a seventh operation S1070 of debonding and picking up the plurality of semiconductor dies from the dicing tape, and an eighth operation S1080 of forming each of the plurality of semiconductor dies into a semiconductor package.

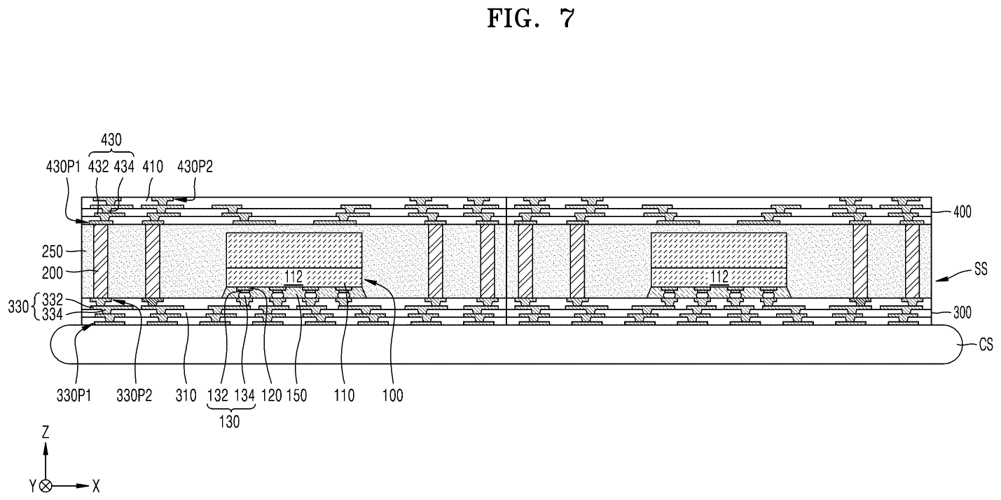

Technical features of each of the first to eighth operations S1010 to S1080 will be described below in detail with reference to FIGS. 7 to 16.

FIGS. 7 to 16 are cross-sectional views showing, in a process sequence, a method of manufacturing a semiconductor package, according to an embodiment.

Referring to FIG. 7, a substrate structure SS formed on a carrier substrate CS may be prepared.

The carrier substrate CS may be a semiconductor substrate, a glass substrate, a ceramic substrate, or a plastic substrate. According to some embodiments, a release film (not shown) may be attached onto the carrier substrate CS and components of the substrate structure SS may be sequentially formed thereon. In other words, the carrier substrate CS may be used as a support substrate to form the substrate structure SS.

In detail, the substrate structure SS may include a first semiconductor chip 100, conductive posts 200 arranged around the first semiconductor chip 100, a first wiring structure 300 disposed below the first semiconductor chip 100, and a second wiring structure 400 disposed on the first semiconductor chip 100.

The substrate structure SS may have a package-on-package (POP) structure. In detail, the substrate structure SS may be a fan-out semiconductor package in which the horizontal width and the horizontal area of the first wiring structure 300 are greater than the horizontal width and the horizontal area of the first semiconductor chip 100. According to some embodiments, the substrate structure SS may be a Fan Out Wafer Level Package (FOWLP) or a Fan Out Panel Level Package (FOPLP).

According to some embodiments, the first wiring structure 300 and the second wiring structure 400 may be formed through a redistribution process. Therefore, the first wiring structure 300 and the second wiring structure 400 may be respectively referred to as a first redistribution structure and a second redistribution structure or may be respectively referred to as a lower redistribution structure and an upper redistribution structure.

The first wiring structure 300 may include a first redistribution insulation layer 310 and a plurality of first redistribution patterns 330. The first redistribution insulation layer 310 may cover the plurality of first redistribution patterns 330. According to some embodiments, the first wiring structure 300 may include a plurality of stacked first redistribution insulation layers 310.

The plurality of first redistribution patterns 330 may include a plurality of first redistribution line patterns 332 and a plurality of first redistribution vias 334. For example, the plurality of first redistribution patterns 330 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof. However, inventive concepts are not limited thereto.

The plurality of first redistribution line patterns 332 may be arranged on at least one of the top surface and the bottom surface of the first redistribution insulation layer 310. For example, when the first wiring structure 300 includes a plurality of stacked first redistribution insulation layers 310, the plurality of first redistribution line patterns 332 may be arranged on the top surface of the uppermost one of the first redistribution insulation layers 310, the bottom surface of the lowermost first redistribution insulation layer 310, and between first redistribution insulation layers 310 adjacent to each other.

The plurality of first redistribution vias 334 may penetrate through the first redistribution insulation layer 310 and be connected to some of the plurality of first redistribution line patterns 332. According to some embodiments, the plurality of first redistribution vias 334 may have a tapered shape in which the horizontal width thereof increases upward in the vertical direction.

According to some embodiments, some of the plurality of first redistribution line patterns 332 may be formed together and integrated with some of the plurality of first redistribution vias 334. For example, a first redistribution line pattern 332 and a first redistribution via 334 contacting the bottom surface of the first redistribution line pattern 332 may be formed together and integrated with each other.

From among the plurality of first redistribution patterns 330, some arranged adjacent to the bottom surface of the first wiring structure 300 may be referred to as a plurality of first bottom surface connection pads 330P1, and some others arranged adjacent to the top surface of the first wiring structure 300 may be referred to as a plurality of first top surface connection pads 330P2. In other words, the plurality of first bottom surface connection pads 330P1 may be some arranged adjacent to the bottom surface of the first wiring structure 300 from among the plurality of first redistribution line patterns 332, and the plurality of first top surface connection pads 330P2 may be some arranged adjacent to the top surface of the first wiring structure 300 from among the plurality of first redistribution line patterns 332.

The plurality of first top surface connection pads 330P2 may be arranged on the top surface of the first redistribution insulation layer 310. For example, when the first wiring structure 300 includes a plurality of stacked first redistribution insulation layers 310, the plurality of first top surface connection pads 330P2 may be arranged on the top surface of the uppermost one of the first redistribution insulation layers 310.

At least one first semiconductor chip 100 may be mounted on the first wiring structure 300. In other words, one first semiconductor chip 100 or a plurality of first semiconductor chips 100 may be provided. The first semiconductor chip 100 may include a semiconductor substrate 110 having an active surface and an inactive surface facing each other, a semiconductor device 112 formed on the active surface of the semiconductor substrate 110, and a plurality of chip pads 120 arranged on the first semiconductor chip 100.

The plurality of chip connecting members 130 may be provided between the plurality of chip pads 120 of the first semiconductor chip 100 and some of the plurality of first top surface connection pads 330P2 of the first wiring structure 300. For example, the plurality of chip connecting members 130 may each be a solder ball or a micro bump. The first semiconductor chip 100 and the first redistribution patterns 330 of the first wiring structure 300 may be electrically connected to each other through the plurality of chip connecting members 130. The plurality of chip connecting members 130 may each include an under bump metal (UBM) layer 132 disposed on a chip pad 120 and a conductive connection member 134 covering the UBM layer 132. The plurality of chip connecting members 130 may include, for example, copper (Cu), aluminum (Al), silver (Ag), tin (Tin), gold (Au), or solder. However, inventive concepts are not limited thereto.

The semiconductor substrate 110 may include, for example, a semiconductor material such as silicon (Si) or germanium (Ge). Alternatively, the semiconductor substrate 110 may include a compound semiconductor material such as silicon carbide (SiC), gallium arsenide (GaAs), indium arsenide (InAs), and indium phosphide (InP). The semiconductor substrate 110 may include a well doped with an impurity, which is a conductive region. The semiconductor substrate 110 may have various device isolation structures such as a shallow trench isolation (STI) structure.

The semiconductor device 112 including a plurality of individual devices of various types may be formed on the active surface of the semiconductor substrate 110. The plurality of individual devices may be electrically connected to the conductive region of the semiconductor substrate 110. The semiconductor device 112 may further include conductive wires or conductive plugs electrically connecting the plurality of individual devices to the conductive region of the semiconductor substrate 110. Also, the individual devices may each be electrically separated from other neighboring individual devices by an insulation film.

According to some embodiments, the first semiconductor chip 100 may include a logic device. For example, the first semiconductor chip 100 may be a central processing unit chip, a graphics processing unit chip, or an application processor chip. According to other embodiments, when the substrate structure SS includes a plurality of first semiconductor chips 100, one of the plurality of first semiconductor chips 100 may be a central processing unit chip, a graphics processing unit chip, or an application processor chip, and another one of the plurality of first semiconductor chips 100 may be a memory semiconductor chip including a memory device.

For example, the memory device may be a non-volatile memory device such as flash memory, phase-change random access memory (PRAM), magnetic random access memory (MRAM), ferroelectric random access memory (FeRAM), or resistive random access memory (RRAM). According to some embodiments, the memory device may be a volatile memory device such as dynamic random access memory (DRAM) or static random access memory (SRAM).

The second wiring structure 400 may include a second redistribution insulation layer 410 and a plurality of second redistribution patterns 430. The second redistribution insulation layer 410 may cover the plurality of second redistribution patterns 430.

According to some embodiments, the second wiring structure 400 may include a plurality of stacked second redistribution insulation layers 410. The plurality of second redistribution patterns 430 may include a plurality of second redistribution line patterns 432 and a plurality of second redistribution vias 434. The plurality of second redistribution patterns 430 may include a metal or a metal alloy. According to some embodiments, the plurality of second redistribution patterns 430 may be formed by stacking a metal or a metal alloy on a seed layer.

The plurality of second redistribution line patterns 432 may be arranged on at least once of the top surface and the bottom surface of the second redistribution insulation layer 410. For example, when the second wiring structure 400 includes a plurality of stacked second redistribution insulation layers 410, the plurality of second redistribution line patterns 432 may be arranged on the top surface of the uppermost one of the second redistribution insulation layers 410, the bottom surface of the lowermost one of the second redistribution insulation layers 410, and between second redistribution insulation layers 410 adjacent to each other.

From among the plurality of second redistribution patterns 430, some arranged adjacent to the bottom surface of the second wiring structure 400 may be referred to as a plurality of second bottom surface connection pads 430P1, and some others arranged adjacent to the top surface of the second wiring structure 400 may be referred to as a plurality of second top surface connection pads 430P2. For example, the plurality of second bottom surface connection pads 430P1 may be some arranged adjacent to the bottom surface of the second wiring structure 400 from among the plurality of second redistribution line patterns 432, and the plurality of second top surface connection pads 430P2 may be some arranged adjacent to the top surface of the second wiring structure 400 from among the plurality of second redistribution line patterns 432. According to other embodiments, the plurality of second bottom surface connection pads 430P1 may be some of the plurality of second redistribution vias 434 arranged adjacent to the bottom surface of the second wiring structure 400.

The plurality of second bottom surface connection pads 430P1 may be arranged on the bottom surface of the second redistribution insulation layer 410. For example, when the second wiring structure 400 includes a plurality of stacked second redistribution insulation layers 410, the plurality of second bottom surface connection pads 430P1 may be arranged on the bottom surface of the lowermost one of the second redistribution insulation layers 410.

The plurality of second top surface connection pads 430P2 may be arranged on the top surface of the second redistribution insulation layer 410. For example, when the second wiring structure 400 includes a plurality of stacked second redistribution insulation layers 410, the plurality of second top surface connection pads 430P2 may be arranged on the top surface of the topmost second redistribution insulation layer 410.

The plurality of second redistribution vias 434 may penetrate through the second redistribution insulation layer 410 and contact and be connected to some of the plurality of second redistribution line patterns 432. According to some embodiments, some of the plurality of second redistribution line patterns 432 may be formed together and integrated with some of the plurality of second redistribution vias 434. For example, a second redistribution line pattern 432 and a second redistribution via 434 contacting the bottom surface of the second redistribution line pattern 432 may be formed together and integrated with each other.

According to some embodiments, the plurality of second redistribution vias 434 may have a tapered shape in which the horizontal width thereof decreases downward in the vertical direction. In other words, the plurality of first redistribution vias 334 and the plurality of second redistribution vias 434 may extend in the same direction and horizontal widths thereof may decrease in the same direction. However, inventive concepts are not limited thereto.

Here, the first redistribution insulation layer 310, the first redistribution patterns 330, the first redistribution line patterns 332, and the first redistribution vias 334 may be referred to as a first insulation layer, first wiring patterns, first wiring line patterns, and first wiring vias, respectively. Also, the second redistribution insulation layer 410, the second redistribution patterns 430, the second redistribution line patterns 432, and the second redistribution vias 434 may be referred to as a second insulation layer, second wiring patterns, second wiring line patterns, and second wiring vias, respectively.

An encapsulant 250 on the top surface of the first wiring structure 300 may cover the first semiconductor chip 100. The encapsulant 250 may fill a space between the first wiring structure 300 and the second wiring structure 400. For example, the encapsulant 250 may be a molding member including an epoxy mold compound (EMC). The encapsulant 250 may further include a filler.

According to some embodiments, an underfill layer 150 surrounding the plurality of chip connecting members 130 may be provided between the first semiconductor chip 100 and the first wiring structure 300. According to some embodiments, the underfill layer 150 may fill a space between the first semiconductor chip 100 and the first wiring structure 300 and may cover lower portions of side surfaces of the first semiconductor chip 100. The underfill layer 150 may be formed through, for example, a capillary underfill process and may include an epoxy resin.

According to some embodiments, side surfaces of the first wiring structure 300, side surfaces of the encapsulant 250, and side surfaces of the second wiring structure 400 may be aligned with one another in the vertical direction to be coplanar with one another.

The plurality of conductive posts 200 through the encapsulant 250 may electrically interconnect the first wiring structure 300 and the second wiring structure 400. The encapsulant 250 may surround the plurality of conductive posts 200.

The plurality of conductive posts 200 may be provided between the first wiring structure 300 and the second wiring structure 400 to be spaced apart from the first semiconductor chip 100 in a horizontal direction. For example, the plurality of conductive posts 200 may be spaced apart from the first semiconductor chip 100 in a horizontal direction and arranged around the first semiconductor chip 100 in an outer region of the first wiring structure 300.

The plurality of conductive posts 200 may be provided between the plurality of first top surface connection pads 330P2 and the plurality of second bottom surface connection pads 430P1. The bottom surfaces of the plurality of conductive posts 200 may be electrically connected to the plurality of first redistribution patterns 330 by contacting the plurality of first top surface connection pads 330P2 of the first wiring structure 300, and the top surface of the conductive posts 200 may be electrically connected to the plurality of second redistribution patterns 430 by contacting the plurality of second bottom surface connection pads 430P1 of the second wiring structure 400.

The bottom surfaces of the plurality of conductive posts 200 may contact the top surfaces of the first top surface connection pads 330P2, respectively. The top surfaces of the plurality of conductive posts 200 may contact the bottom surfaces of the second bottom surface connection pads 430P1, respectively.

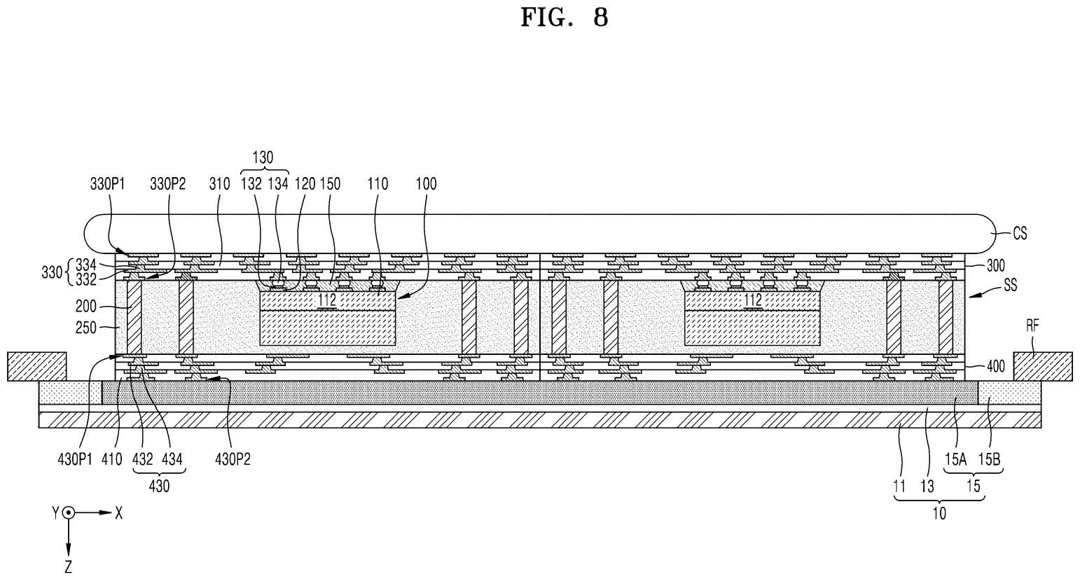

Referring to FIG. 8, an exposed surface of the substrate structure SS may be attached to the dicing tape 10.

The carrier substrate CS may be mounted such that the exposed surface of the substrate structure SS is adhered onto the first adhesive film 15A of the adhesive layer 15 of the dicing tape 10. Prior to this, as shown in FIG. 8, the second adhesive film 15B of the adhesive layer 15 in the dicing tape 10 may be attached to a lower portion of a ring frame RF. The ring frame RF may have a circular ring-like shape, and the inner diameter of the ring frame RF may be about 400 mm but is not limited thereto.

The substrate structure SS having attached thereto the carrier substrate CS may be attached onto the first adhesive film 15A of the adhesive layer 15 of the dicing tape 10 such that the second wiring structure 400 formed on the substrate structure SS faces the first adhesive film 15A of the adhesive layer 15.

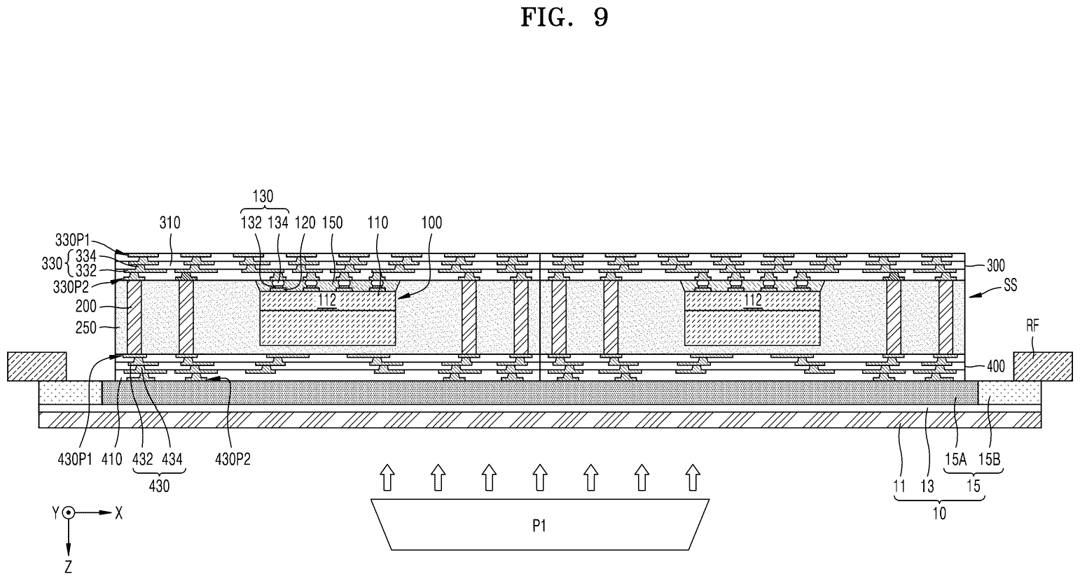

Referring to FIG. 9, an ultraviolet ray P1 may be irradiated to the dicing tape 10 to which the substrate structure SS is attached.

The ultraviolet ray P1 may be irradiated toward a lower portion of the dicing tape 10, that is, toward the base layer 11 of the dicing tape 10. Due to the pre-processing process using the ultraviolet ray P1, the adhesive force of the adhesive layer 15 constituting the dicing tape 10 may increase or decrease. Here, the adhesive force of the adhesive layer 15 may increase or decrease differently in the first adhesive film 15A and the second adhesive film 15B. According to some embodiments, the adhesive force of the first adhesive film 15A may slightly increase, but the adhesive force of the second adhesive film 15B may significantly increase. According to other embodiments, the adhesive force of the first adhesive film 15A may be significantly reduced, but the adhesive force of the second adhesive film 15B may be slightly reduced.

Therefore, the ring frame RF may be strongly bonded onto the second adhesive film 15B of the adhesive layer 15. Also, the substrate structure SS may be suitably bonded to the first adhesive film 15A of the adhesive layer 15 for subsequent processes.

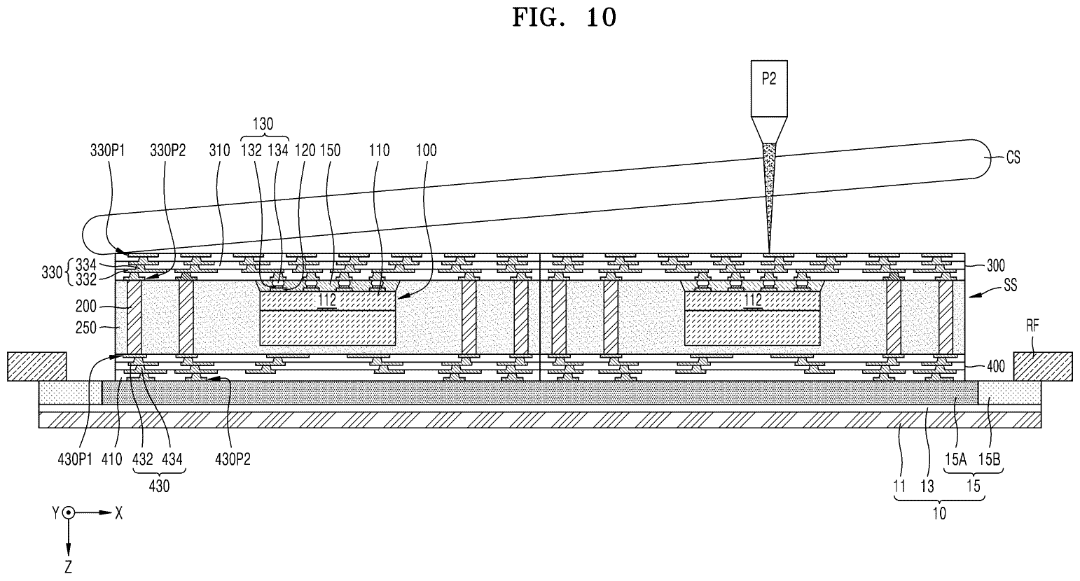

Referring to FIG. 10, the carrier substrate CS may be separated from the substrate structure SS.

To separate and remove the carrier substrate CS, a laser beam P2 may be irradiated to the carrier substrate CS. By irradiation of the laser beam P2, the bonding force between the substrate structure SS and the carrier substrate CS may be weakened, and the carrier substrate CS may be completely separated.

To facilitate separation of the carrier substrate CS, an adhesive layer (not shown) may be disposed between the carrier substrate CS and the substrate structure SS. The adhesive layer may be in a liquid form or a gel form that may be easily deformed by a certain amount of heat caused by irradiation of the laser beam P2.

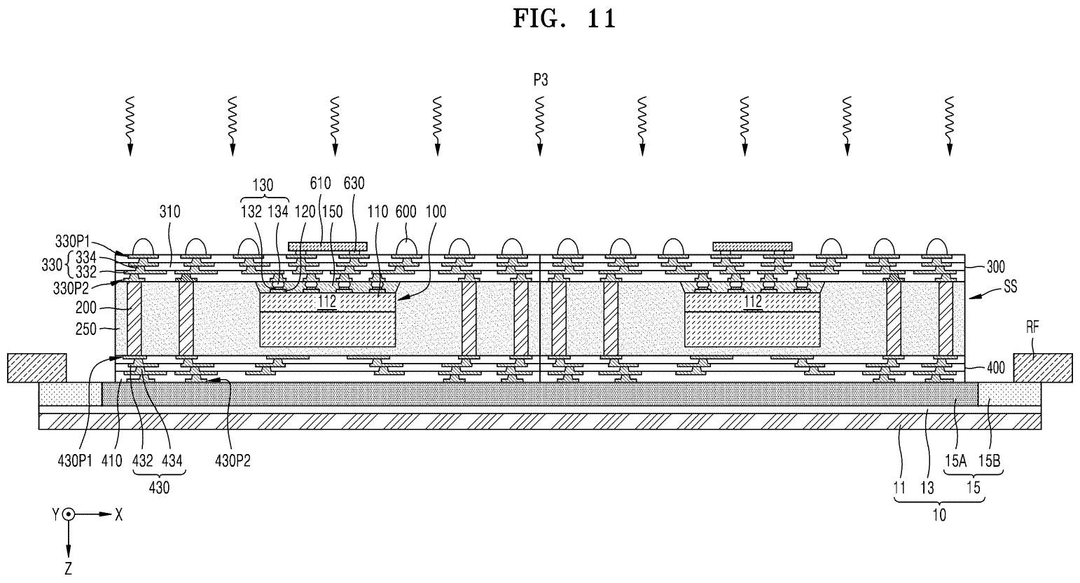

Referring to FIG. 11, a plurality of external connection terminals 600 may be attached to some of the plurality of first bottom surface connection pads 330P1, and passive devices 610 may be attached to some other ones of the plurality of first bottom surface connection pads 330P1. The external connection terminals 600 and passive devices 610 may be attached to corresponding connection pads 330P1 using a sufficient pressure force P3.

The plurality of external connection terminals 600 may be formed on the top surface of the first wiring structure 300. The plurality of external connection terminals 600 may include, for example, solder balls, conductive bumps, conductive paste, ball grid array (BGA), lead grid array (LGA), pin grid array (PGA), or a combination thereof.

A passive device 610 may include at least one selected from among a resistor, a capacitor, an inductor, a thermistor, an oscillator, a ferrite bead, an antenna, and a varistor. For example, the passive device 610 may include a Multi Layer Ceramic Capacitor (MLCC), a Low Inductance Chip Capacitor (LICC), a Land Side Capacitor (LSC), and an Integrated Passive Device (IPD) but is not limited thereto.

To attach the plurality of external connection terminals 600 and the passive devices 610 to the plurality of first bottom surface connection pads 330P1, a reflow process may be performed. After the solder constituting the plurality of external connection terminals 600 is melted by the reflow process, the plurality of external connection terminals 600 may be arranged in a ball-like shape on the plurality of first lower connection pads 330P1 due to surface tension without collapsing. According to some embodiments, an intermetallic compound may be formed at the interface between the plurality of external connection terminals 600 and the plurality of first bottom surface connection pads 330P1.

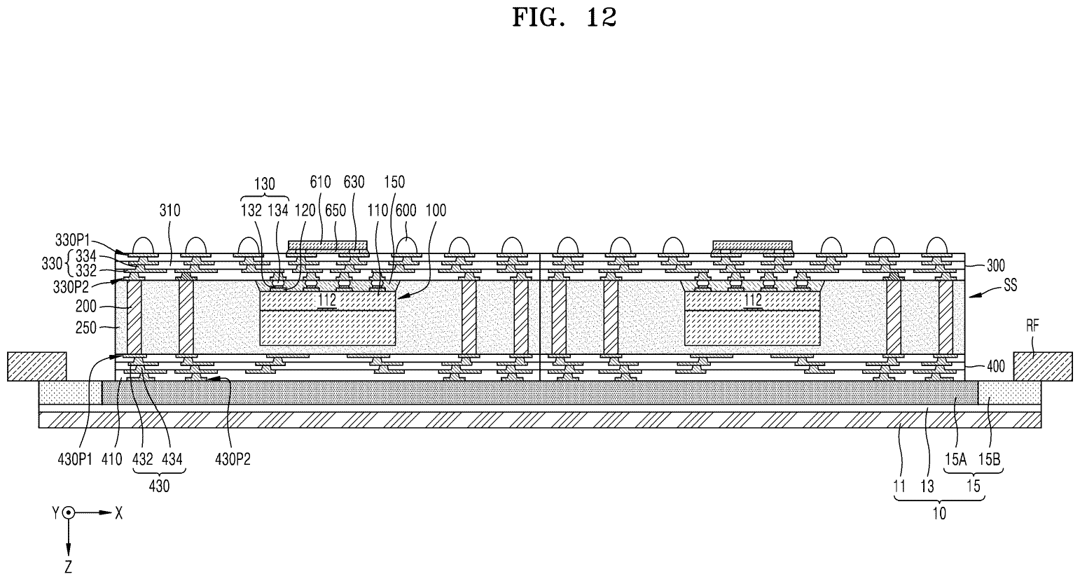

Referring to FIG. 12, the space between the passive device 610 and the first wiring structure 300 may be filled with an underfill layer 650.

The underfill layer 650 may surround the sidewall of a solder bump 630 disposed below the passive device 610 and fill the gap between solder bumps 630 adjacent to each other. In the process of electrically connecting the passive device 610 and the solder bump 630, a gap may be formed between the passive device 610 and the solder bump 630. Since such a gap may cause problems in the reliability of the connection between the passive device 610 and the solder bump 630, the underfill layer 650 may be injected and cured to reinforce the connection.

The passive device 610 may be more stably fixed on the solder bump 630 by the underfill layer 650, and, despite the difference in thermal expansion coefficient between the passive device 610 and the solder bump 630, the passive device 610 and the solder bump 630 may not be electrically separated from each other.

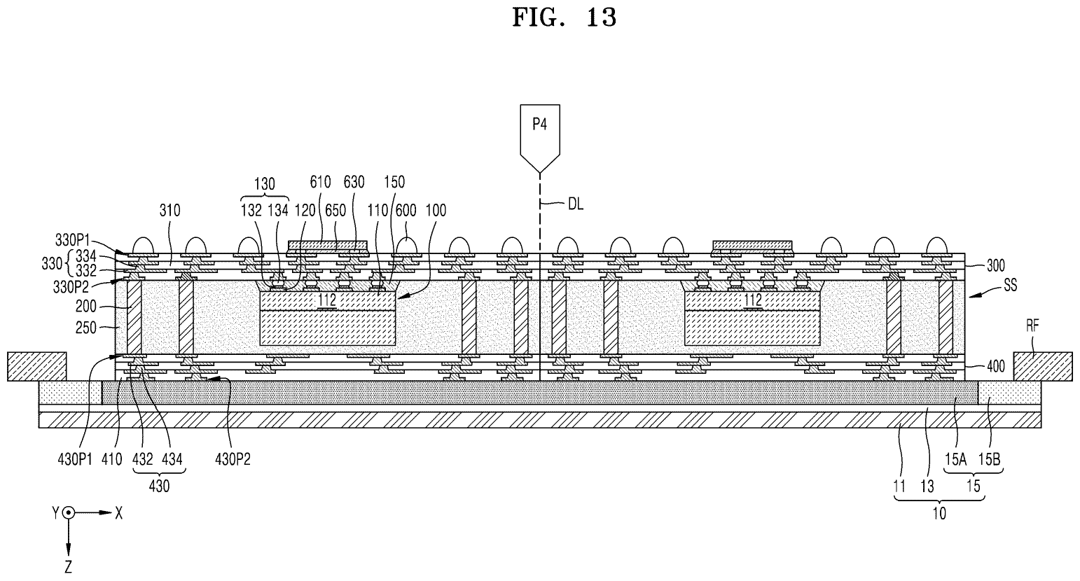

Referring to FIG. 13, various components including the first wiring structure 300 of the substrate structure SS may be cut (P4) along the dicing line DL.

Since the substrate structure SS may be a fan-out wafer level package or a fan-out panel level package, various types of material films including the first wiring structure 300 may be cut (P4) along the dicing line DL, and thus the substrate structure SS may be physically separated into individual semiconductor dies. Although only one dicing line DL is shown in the diagram, inventive concepts are not limited thereto.

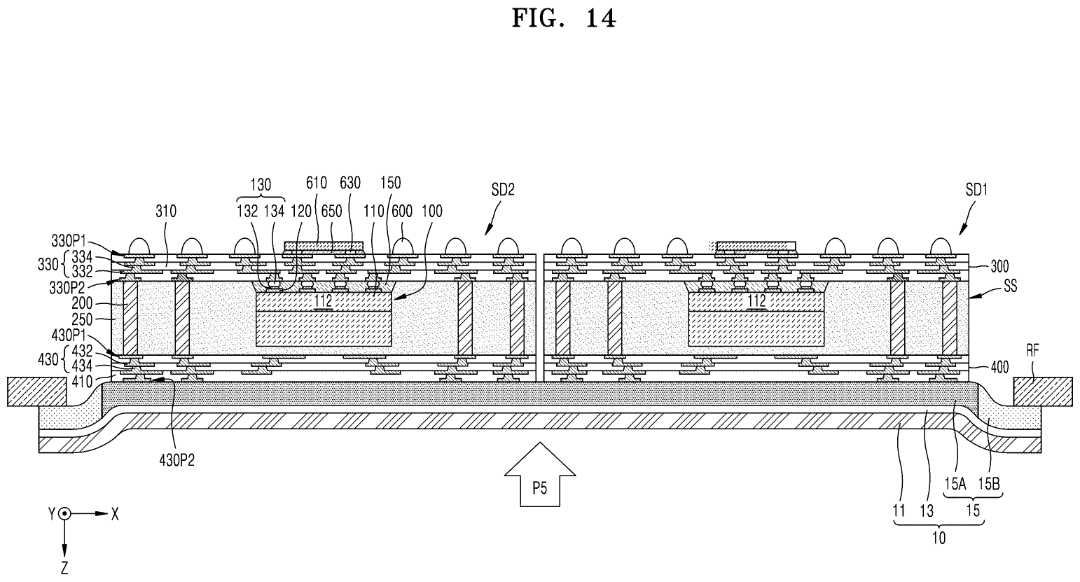

Referring to FIG. 14, pressure P5 may be provided to the lower portion of the dicing tape 10 to expand the surface area of the dicing tape 10.

According to some embodiments, a jig (not shown) may be attached below the dicing tape 10 and the jig may be pushed up to expand the dicing tape 10. In other words, mechanical pressure P5 may be provided to the lower portion of the dicing tape 10.

As the dicing tape 10 expands, the substrate structure SS (refer to FIG. 13) may be physically separated into a first semiconductor die SD1 and a second semiconductor die SD2 around the dicing line DL (refer to FIG. 13). Although only the first semiconductor die SD1 and the second semiconductor die SD2 are shown in the diagram, the number of semiconductor dies is not limited thereto.

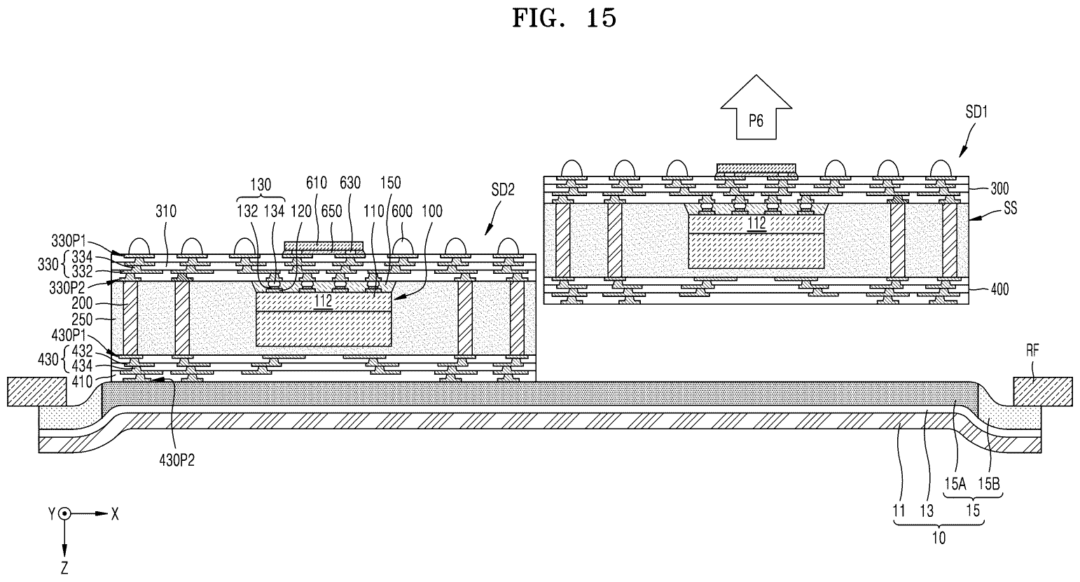

Referring to FIG. 15, the first semiconductor die SD1 may be picked up (P6) from the dicing tape 10 by using a pick-up device.

The first adhesive force of the first adhesive film 15A of the adhesive layer 15 constituting the dicing tape 10 may be within a range that allows the first semiconductor die SD1 to be easily picked up (P6) from the dicing tape 10, and the second adhesive force of the second adhesive film 15B of the adhesive layer 15 may be within a range that provides strong bonding to prevent the ring frame RF from being separated from the dicing tape 10 during the pick-up P6 process. Therefore, the pick-up properties of the first semiconductor die SD1 may be improved without delamination of the ring frame RF from the dicing tape 10 during the pick-up P6 process.

According to some embodiments, a wet cleaning process may be performed to remove adhesive residue that may remain on a surface of the first semiconductor die SD1 exposed as the dicing tape 10 is removed. The wet cleaning process may be performed by using an organic solvent or an inorganic solvent depending on the material of the adhesive layer 15 constituting the dicing tape 10.

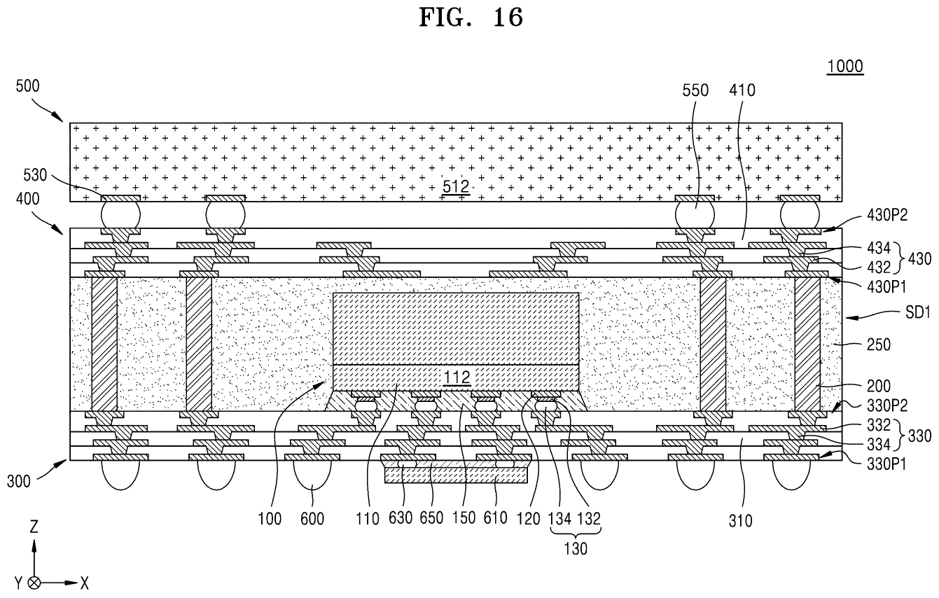

Referring to FIG. 16, a second semiconductor chip 500 may be mounted to be electrically connected to the second wiring structure 400 of the first semiconductor die SD1.

The second semiconductor chip 500 may be mounted on the second wiring structure 400 such that the plurality of second pads 530 face the second wiring structure 400. The second semiconductor chip 500 may be electrically connected to the plurality of first redistribution patterns 330 of the first wiring structure 300 through the plurality of internal connection terminals 550 attached to the plurality of second pads 530, the plurality of second redistribution patterns 430, and the plurality of conductive posts 200. In this way, the semiconductor package 1000 may be completely manufactured.

As described above, according to the method of manufacturing the semiconductor package 1000 according to inventive concepts, by using the first adhesive film 15A (refer to FIG. 15) and the second adhesive film 15B (refer to FIG. 15) having different adhesive forces, the ring frame 20 (refer to FIG. 15) is strongly attached to the second adhesive film 15B (refer to FIG. 15) of the dicing tape 10 (refer to FIG. 15) while the semiconductor die may be easily separated from the first adhesive film 15A (refer to FIG. 15) of the dicing tape 10 (refer to FIG. 15), and thus the pick-up properties of a semiconductor die from the dicing tape 10 (refer to FIG. 15) may be improved.

Also, a semiconductor wafer may be transferred by using dicing tapes 10, 20, and 30 according to inventive concepts described above. In other words, by transferring a semiconductor wafer by using the dicing tapes 10, 20, and 30 as transfer substrates, a semiconductor package may be manufactured without using (or using less frequently) a carrier substrate.

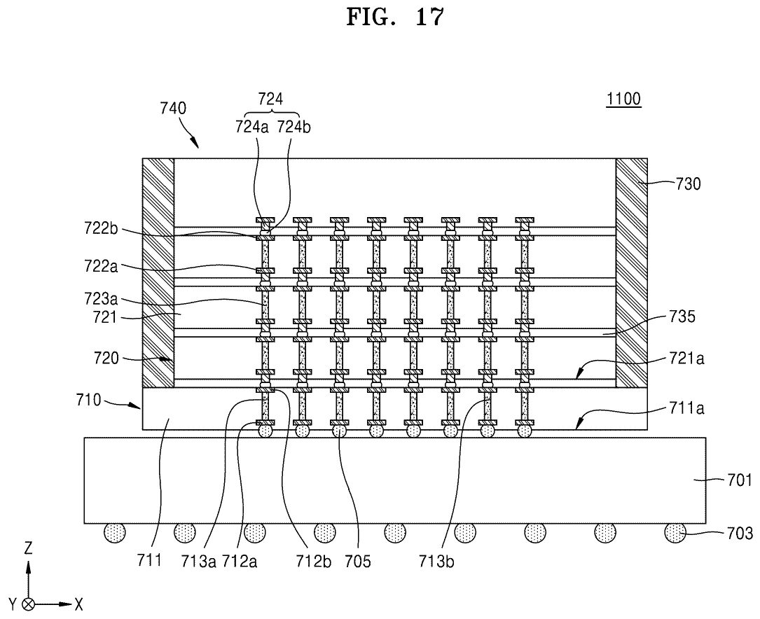

FIGS. 17 to 19 are views showing other semiconductor packages manufactured by the method of manufacturing a semiconductor package, according to an embodiment.

Referring to FIG. 17, a semiconductor package 1100 may include stacked semiconductor chips 740 stacked on a package substrate 701.

The package substrate 701 may be a printed circuit board (PCB). Also, solder bumps 703, which are external connection terminals, may be formed on the bottom surface of the package substrate 701.

The stacked semiconductor chips 740 may include a first semiconductor chip 710 and a plurality of second semiconductor chips 720 mounted on the first semiconductor chip 710. The second semiconductor chips 720 may be sequentially stacked on the first semiconductor chip 710 in a vertical direction (Z direction). The width of the first semiconductor chip 710 may be greater than the width of each of the second semiconductor chips 720.

Although the diagram shows that the stacked semiconductor chips 740 include four second semiconductor chips 720, inventive concepts are not limited thereto. For example, the stacked semiconductor chips 740 may include two or more second semiconductor chips 720. The first semiconductor chip 710 and the second semiconductor chips 720 may be manufactured by using the dicing tapes 10, 20, and 30 according to inventive concepts described above.

The first semiconductor chip 710 may each include a first pad 712a and a second pad 712b on both surfaces of a first semiconductor substrate 711. The first pad 712a and the second pad 712b may be electrically connected to each other by using a first through-via structure 713a. The first pad 712a may be electrically connected to the package substrate 701 through a solder bump 705, which is an external connection terminal. An active surface 711a of the first semiconductor chip 710 may be positioned downward. The first pad 712a may be an upper pad, and the second pad 712b may be a lower pad.

The second semiconductor chips 720 may each include a third pad 722a and a fourth pad 722b on both surfaces of a second semiconductor substrate 721. The third pad 722a and the fourth pad 722b may be electrically connected to each other by using a second through-via structure 723a. The third pad 722a may electrically interconnect the second semiconductor chips 720 through an internal connection terminal 724. The internal connection terminal 724 may include an internal connection pad 724a and an internal bump 724b. An active surface 721a of each of the second semiconductor chips 720 may be positioned downward. The third pad 722a may be an upper pad, and the fourth pad 722b may be a lower pad.

In the stacked semiconductor chip 740, the second semiconductor chips 720 may be adhered to each other by an adhesive layer 735. The second semiconductor chips 720 may be molded on the first semiconductor chip 710 by a molding layer 730.

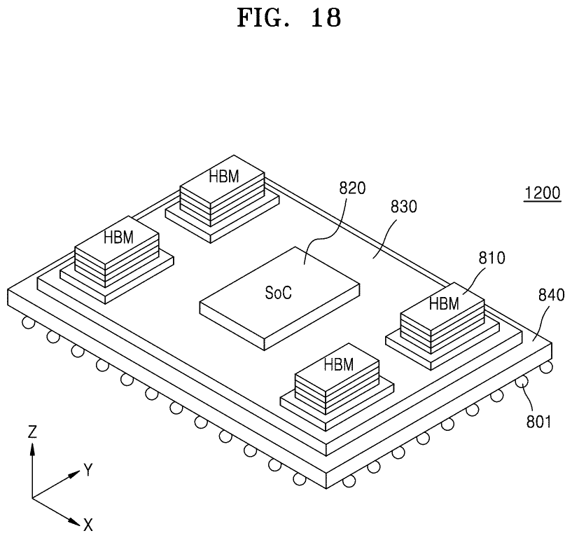

Referring to FIG. 18, a semiconductor package 1200 may include a plurality of stacked memory chips 810 and a system-on-chip 820.

The stacked memory chips 810 and the system-on-chip 820 may be stacked on an interposer chip 830, and the interposer chip 830 may be stacked on a package substrate 840. The interposer chip 830 may be manufactured by using the dicing tapes 10, 20, and 30 according to inventive concepts described above.

The semiconductor package 1200 may transmit and receive signals to and from other external packages or electronic devices through solder balls 801 attached to the bottom of the package substrate 840.

Each of the stacked memory chips 810 may be implemented based on the High Bandwidth Memory (HBM) standard. However, inventive concepts are not limited thereto, and each of the stacked memory chips 810 may be implemented based on the GDDR standard, the HMC standard, or the Wide I/O standard. Each of the stacked memory chips 810 may be manufactured by using the dicing tapes 10, 20, and 30 according to inventive concepts described above.

The system-on-chip 820 may include at least one processor, such as an application processor (AP), a central processing unit (CPU), and a graphics processing unit (GPU), and a memory controller for controlling the plurality of stacked memory chips 810. The system-on-chip 820 may transmit and receive signals to and from corresponding stacked memory chips through the memory controller.

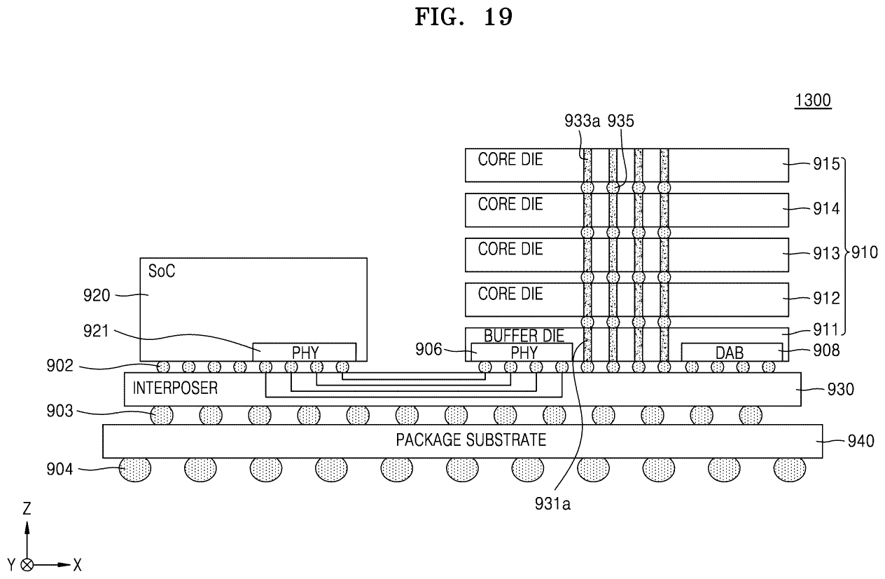

Referring to FIG. 19, a semiconductor package 1300 may include a stacked memory chip 910, a system-on-chip 920, an interposer chip 930, and a package substrate 940.

The interposer chip 930 may be manufactured by using the dicing tapes 10, 20, and 30 according to inventive concepts described above. Also, the stacked memory chip 910 may include a buffer die 911 and core dies 912 to 915. The stacked memory chips 910 may be manufactured by using the dicing tapes 10, 20, and 30 according to inventive concepts described above.

The core dies 912 to 915 may each include memory cells for storing data. The buffer die 911 may include a physical layer 906 and a direct access region 908. The physical layer 906 may be electrically connected to a physical layer 921 of the system-on-chip 920 through the interposer chip 930. The stacked memory chip 910 may receive signals from the system-on-chip 920 or may transmit signals to the system-on-chip 920 through the physical layer 906.

The direct access region 908 may provide an access path to test the stacked memory chip 910 without using the system-on-chip 920. The direct access region 908 may include conductive means (e.g., a port or a pin) capable of directly communicating with an external test device. A test signal received through the direct access region 908 may be transmitted to the core dies 912 to 915 through through-via structures. For testing of the core dies 912 to 915, data read from the core dies 912 to 915 may be transmitted to a test device through the through-via structures and the direct access region 908. Accordingly, a direct access test for the core dies 912 to 915 may be performed.

The buffer die 911 and the core dies 912 to 915 may be electrically connected to each other through through-via structures 931a and 933a and bumps 935. The buffer die 911 and the core dies 912 to 915 may be manufactured by using the dicing tapes 10, 20, and 30 according to inventive concepts described above.

For example, the buffer die 911 may include a first through-via structure 931a. The core dies 912 to 915 may each include a second through-via structure 933a. The buffer die 911 may receive signals provided to respective channels from the system-on-chip 920 through bumps 902 allocated for the respective channels or transmits signals through the bumps 902 to the system-on-chip 920. For example, the bumps 902 may be micro bumps.

The system-on-chip 920 may execute applications supported by the semiconductor package 1300 by using the stacked memory chip 910. The system-on-chip 920 may be manufactured by using the dicing tapes 10, 20, and 30 according to inventive concepts described above.

The system-on-chip 920 may control overall operations of the stacked memory chip 910. The system-on-chip 920 may include the physical layer 921. The physical layer 921 may include an interface circuit for transmitting and receiving signals to and from the physical layer 906 of the stacked memory chip 910. The system-on-chip 920 may provide various signals to the physical layer 906 through the physical layer 921. Signals provided to the physical layer 906 may be transmitted to the core dies 912 to 915 through the interface circuit of the physical layer 906 and the through-via structures 931a and 933a.

The interposer chip 930 may interconnect the stacked memory chip 910 and the system-on-chip 920. The interposer 930 may interconnect the physical layer 906 of the stacked memory chip 910 and the physical layer 921 of the system-on-chip 920 and provide physical paths formed using a conductive material. Therefore, the stacked memory chip 910 and the system-on-chip 920 may be stacked on the interposer chip 930 and exchange signals with each other.

Bumps 903 may be attached to an upper portion of the package substrate 940, and solder balls 904 may be attached to a lower portion of the package substrate 940. For example, the bumps 903 may be flip-chip bumps. The interposer chip 930 may be stacked on the package substrate 940 through the bumps 503. The semiconductor package 1300 may transmit and receive signals to and from other external packages or external electronic devices through the solder balls 904.

While inventive concepts has been particularly shown and described with reference to embodiments thereof, it will be understood that various changes in form and details may be made therein without departing from the spirit and scope of the following claims.

What is claimed is:

1. A dicing tape comprising:
a base layer;
an intermediate layer on the base layer; and
an adhesive layer on the intermediate layer, wherein
the adhesive layer includes a first adhesive film and a second adhesive film,
the first adhesive film has a circular shape in a central portion of the adhesive layer and has a first adhesive force,
the second adhesive film surrounds the first adhesive film to provide an interface between the first adhesive film and the second adhesive film,
the second adhesive film has a second adhesive force, and
the second adhesive force is greater than the first adhesive force.

2. The dicing tape of claim 1, wherein a level of a top surface of the first adhesive film and a level of a top surface of the second adhesive film are equal to each other.

3. The dicing tape of claim 1, wherein
the first adhesive film and the second adhesive film are different films arranged side-by-side on a top surface of the intermediate layer, and
the interface between the first adhesive film and the second adhesive film is in a vertical direction with respect to the top surface of the intermediate layer.

4. The dicing tape of claim 1, wherein
a thickness of the base layer is greater than a thickness of the adhesive layer,
the thickness of the adhesive layer is greater than a thickness of the intermediate layer, and
the thickness of the adhesive layer is 20 μm to 30 μm.

5. The dicing tape of claim 4, wherein a thickness of the first adhesive film and a thickness of the second adhesive film are equal to each other.

6. The dicing tape of claim 1, wherein
a top surface of the first adhesive film is an embossed surface, and
a top surface of the second adhesive film is flat.

7. The dicing tape of claim 6, wherein a level of a topmost surface of the first adhesive film is higher than a level of a topmost surface of the second adhesive film.

8. The dicing tape of claim 7, wherein a thickness of the first adhesive film is greater than a thickness of the second adhesive film.

9. The dicing tape of claim 1, wherein
the first adhesive film comprises a pressure sensitive adhesive (PSA),
the second adhesive film comprises a PSA, and
a degree of curing in the first adhesive film is higher than a degree of curing in the second adhesive film.

10. The dicing tape of claim 1, wherein
the base layer comprises one of polyethylene terephthalate (PET), polyethylene naphthalate (PEN), polyether ether ketone (PEEK), or polyimide (PI), and
the intermediate layer comprises an ultraviolet (UV) curable synthetic resin or a non-UV curable synthetic resin.

11. A dicing tape comprising:
a base layer;
an intermediate layer on the base layer; and
an adhesive layer on the intermediate layer, wherein
the adhesive layer includes a first adhesive film, a second adhesive film, and a third adhesive film,
the first adhesive film has a circular shape in a central portion of the adhesive layer and has a first adhesive force,
the second adhesive film has a ring-like shape and surrounds the first adhesive film to provide a first interface between the first adhesive film and the second adhesive film,
the second adhesive film has a second adhesive force,
the second adhesive force is greater than the first adhesive force,
the third adhesive film that surrounds the second adhesive film to provide a second interface between the second adhesive film and the third adhesive film, and
the third adhesive film has the first adhesive force.

12. The dicing tape of claim 11, wherein a level of a top surface of the first adhesive film, a level of a top surface of the second adhesive film, and a level of a top surface of the third adhesive film are equal to one another.

13. The dicing tape of claim 11, wherein
the first adhesive film, the second adhesive film, and the third adhesive film are different films arranged side-by-side on a top surface of the intermediate layer, and
the first interface between the first adhesive film and the second adhesive film and the second interface between the second adhesive film and the third adhesive film are each in a vertical direction with respect to the top surface of the intermediate layer.

14. The dicing tape of claim 11, wherein
a thickness of the base layer is greater than a thickness of the adhesive layer,
the thickness of the adhesive layer is greater than a thickness of the intermediate layer,
the thickness of the adhesive layer is 20 μm to 30 μm, and
a thickness of the first adhesive film, a thickness of the second adhesive film, and a thickness of the third adhesive film are equal to one another.

15. The dicing tape of claim 11, wherein
the first adhesive film, the second adhesive film, and the third adhesive film each comprise a pressure-sensitive adhesive,
a degree of curing in the first adhesive film and a degree of curing in the third adhesive film both are higher than a degree of curing in the second adhesive film.

16. A method of manufacturing a semiconductor package, the method comprising:
preparing a substrate structure with a first surface attached to a carrier substrate;
attaching a ring frame to edges of a dicing tape;
attaching a second surface of the substrate structure to a center of the dicing tape, the second surface of the substrate structure being opposite the first surface of the substrate structure;
performing an ultraviolet (UV) treatment process on the carrier substrate;
irradiating a laser beam to the carrier substrate to separate the carrier substrate from the substrate structure;
attaching solder balls to the first surface of the substrate structure and performing a heat treatment process thereon;
separating the substrate structure into a plurality of semiconductor dies by cutting the substrate structure along a dicing line;
debonding and picking up the plurality of semiconductor dies from the dicing tape; and
forming each of the plurality of semiconductor dies into a semiconductor package, wherein
the dicing tape includes a base layer, an intermediate layer on the base layer, and an adhesive layer on the intermediate layer,
the adhesive layer includes a first adhesive film and a second adhesive film,
the first adhesive film has a circular shape in a central portion of the adhesive layer and has a first adhesive force,
the second adhesive film surrounds the first adhesive film to provide an interface with between the first adhesive film and the second adhesive film,
the second adhesive film has a second adhesive force, and
the second adhesive force is greater than the first adhesive force.

17. The method of claim 16, wherein
the attaching the second surface of the substrate structure to the center of the dicing tape includes attaching the substrate structure to the first adhesive film of the dicing tape, and
the attaching the ring frame to the edges of the dicing tape include attaching the ring frame is attached to the second adhesive film of the dicing tape.

18. The method of claim 16, wherein,
in the debonding and picking up of the plurality of semiconductor dies, a force needed for the debonding is greater than the first adhesive force and less than the second adhesive force.

19. The method of claim 16, wherein
a level of a top surface of the first adhesive film and a level of a top surface of the second adhesive film are equal to each other, and
the interface between the first adhesive film and the second adhesive film is in a vertical direction with respect to the top surface of the intermediate layer.

20. The method of claim 16, wherein a diameter of the first adhesive film is greater than a diameter of the substrate structure and less than an inner diameter of the ring frame.
